(19) United States
(12) Patent Application Publication
(10) Pub. No.: US 2009/0107951 A1
(43) Pub. Date: Apr. 30, 2009

(54) Method of packaging an LED array module

(76) Inventor: Ming-Che Wu, Tsao Tuen (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/976,923

(22) Filed: Oct. 30, 2007

(51) Int. Cl. B29D 11/00

(52) U.S. Cl. 216/24

(57) ABSTRACT

A method for packaging an LED array module includes: forming at least one concave groove on a drive IC structure; arranging at least one LED array in the at least one concave groove; solidifying a plurality of liquid conductive materials to form a plurality of conductive elements that is electrically connected between the drive IC structure and the at least one LED array via a printing, a coating, a stamping, or a stencil printing process; disposing the drive IC structure on a PCB with at least one input/output pad; and then forming a conductive structure that is electrically connected between the drive IC structure and the at least one input/output pad.

### BACKGROUND OF THE INVENTION

1. Field of the Invention

The present invention relates to a method of packaging an LED array module, and particularly relates to a method of packaging an LED array module via printing, coating, stamping or stencil printing.

2. Description of the Related Art

In the typical printer technology, a laser is used as a light source in a printer head to scan and transfer the printing information as light signals to a rotating drum in order to generate electrostatic latent images formed on the rotating drum. Moreover, the printing method further includes a toner absorbing step, a transferring step, a hot pressing step, an electrostatic discharging step etc. to achieve printing requirement. However, a laser printer head of the prior art has many optical components, and the mechanism of the laser printer head is complex and the optical path of the laser printer head is very longer. Hence, the optical structure is quite complex and difficult to reduce in size for using a laser in this way. Therefore, the current trend is toward using light emitting diodes to replace lasers as the light sources in printer heads, which can simplify the optical structure.

A further requirement is to reduce the volume of each light emitting diode so as to increase the resolution of the printer. More light emitting diodes may be constructed per unit area in the printer head when the volume of each light emitting diode is reduced. According to the typical packaging method, a highly precise packaging apparatus is required to arrange the light emitting diode arrays and the driver integrated circuits so that they are exactly parallel to each other in a printed circuit board. Then, a wire bonding process is performed to form about 5000 wires between the light emitting diode arrays and the driver integrated circuits if the resolution of the printer is 600 dpi (dots per inch) of A4 size paper. The driver integrated circuits drive the light emitting diode arrays through these wires.

A highly exact and dense wire bonding process in the foregoing method increases the difficulty of the packaging process. This reduces the product yield and indirectly raises the manufacturing cost. Moreover, reducing the volume of the light emitting diodes, although increasing the resolution of the printer, further increases the packaging difficulty.

Therefore, a new package structure and method thereof is required to resolve the foregoing problems.

### SUMMARY OF THE INVENTION

One particular aspect of the present invention is to provide a method of packaging an LED array module. The LED array module is a light exposure module that can be applied to EPG (Electrophotography) printer.

Moreover, the feature of the present invention includes: etching at least one concave groove on the drive IC structure; arranging a light-emitting element array such as an LED array in the at least one concave groove; and then achieving high density electrical connection with 600-1200 dpi via printing, coating, stamping or stencil printing. Hence, the present invention can reduce product size, material cost, and manufacturing cost due to high density electrical connection.

In order to achieve the above-mentioned aspects, the present invention provides a method of packaging an LED array module including: forming at least one concave groove on a top side of a drive IC structure; receiving at least one LED array in the at least one concave groove; and solidifying a plurality of liquid conductive materials to form a plurality of conductive elements electrically connected between the drive IC structure and the at least one LED array.

Moreover, before receiving the at least one LED array in the at least one concave groove, the method further includes “forming an adhesive element on a lower surface of the at least one LED array” or “forming an adhesive element on a base surface of the at least one concave groove” for making the adhesive element formed between the at least one LED array and the drive IC structure.

Furthermore, before the step of solidifying the liquid conductive material, the method further comprises: forming an insulative layer on the drive IC structure and the at least one LED array; and patterning the insulative layer to form a patterned insulative layer for covering over two width gaps formed between the at least one LED array and the drive IC structure and exposing the drive IC pads and the LED pads.

Moreover, the step of solidifying the liquid conductive material further comprises following three aspects:

The first aspect includes: forming each liquid conductive material between each corresponding drive IC pad and each corresponding LED pad via printing or coating; curing the liquid conductive materials to make the liquid conductive materials become the conductive elements; and removing a part of the patterned insulative layer formed on the at least one LED array to accomplish the LED array module.

The second aspect includes: forming each liquid conductive material between each corresponding drive IC pad and each corresponding LED pad via stamping; curing the liquid conductive materials to make the liquid conductive materials become the conductive elements; and removing a part of the patterned insulative layer formed on the at least one LED array to accomplish the LED array module.

The third aspect includes: arranging a stencil on the patterned insulative layer, wherein the stencil has a predetermined pattern corresponding to the patterned insulative layer; forming each liquid conductive material between each corresponding drive IC pad and each corresponding LED pad via stencil printing; curing the liquid conductive materials to make the liquid conductive materials become the conductive elements; and removing a part of the patterned insulative layer formed on the at least one LED array to accomplish the LED array module.

In addition, after the step of solidifying the liquid conductive material, the method further includes: arranging the drive IC structure on a PCB that has at least one input/output pad; and forming a conductive structure electrically connected between the drive IC structure and the at least one input/output pad.

Hence, the present invention utilize printing, coating, stamping or stencil printing to manufacture a conductive structure for electrically connecting between the at least one LED array and the drive IC structure without using wire-bonding process such as prior art that needs to take a long time. Hence, the present invention not only can reduce product size, material cost, and manufacturing cost, but also increases production speed.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a flow chart of a method of packaging an LED array module according to the first embodiment of the present invention;

FIG. 2 is a schematic view of a wafer that has been patterned;

FIG. 3 is an enlarged view of A part of FIG. 2;

FIG. 4 is a cross-sectional view along line 4-4 of FIG. 2;

FIGS. 5A1 to 5G are cross-sectional, schematic views of a packaging process according to the first embodiment of the present invention;

FIG. 6 is a flow chart of a method of packaging an LED array module according to the second embodiment of the present invention;

FIGS. 7A to 7E are cross-sectional, schematic views of a packaging process according to the second embodiment of the present invention;

FIG. 8 is a flow chart of a method of packaging an LED array module according to the third embodiment of the present invention; and

FIGS. 9A to 9C are cross-sectional, schematic views of a packaging process according to the second embodiment of the present invention.

### DETAILED DESCRIPTION OF THE PREFERRED EMBODIMENTS

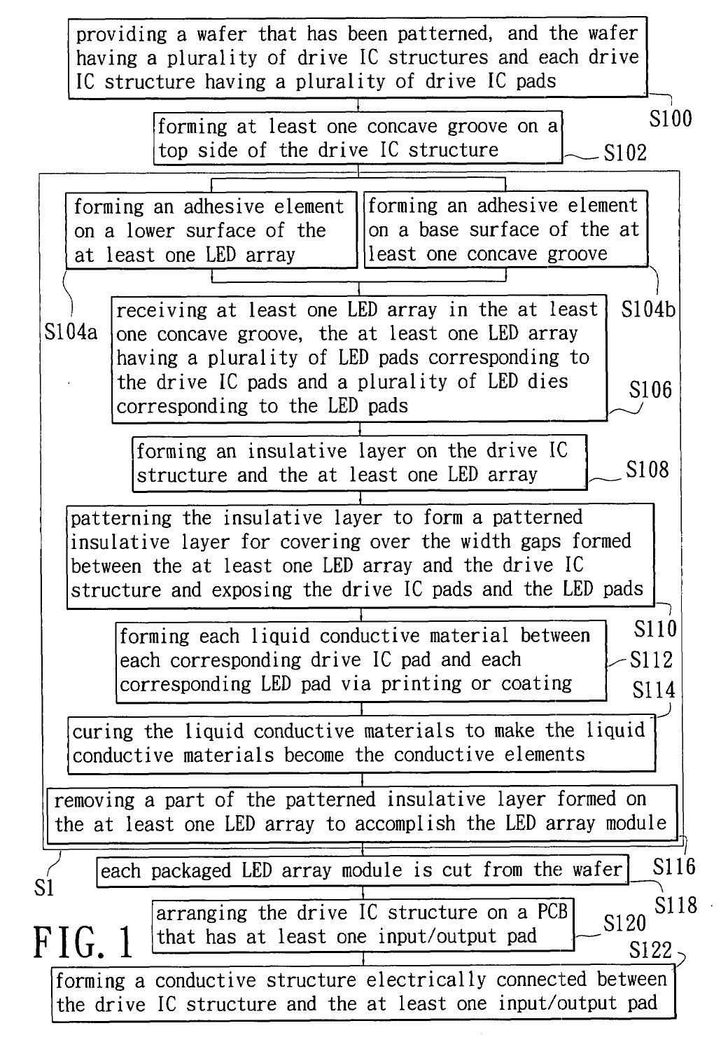

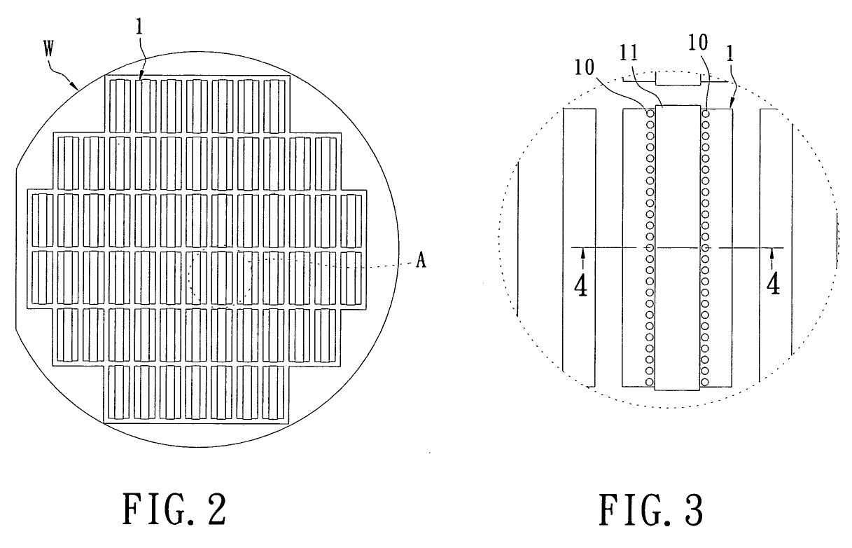

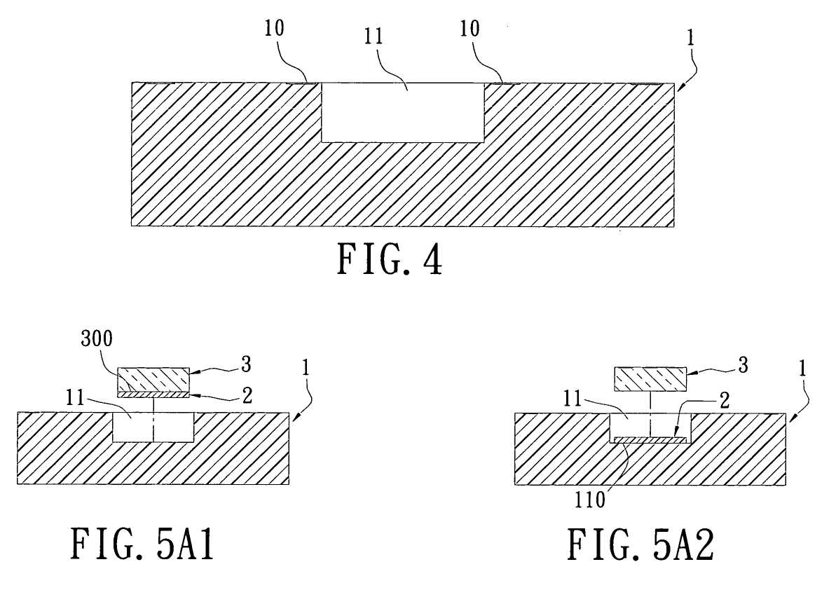

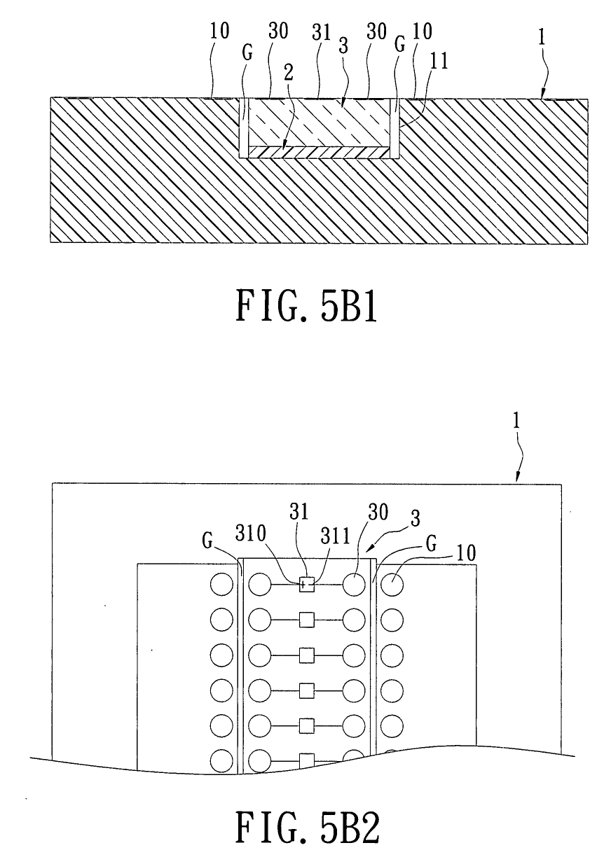

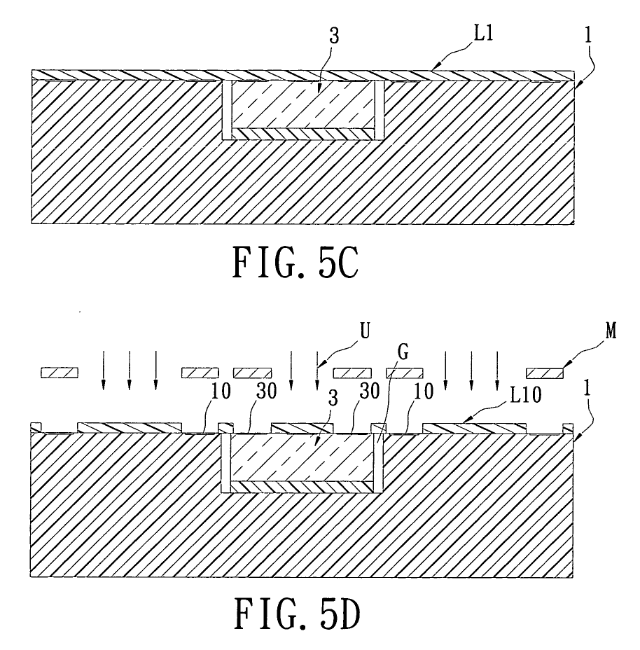

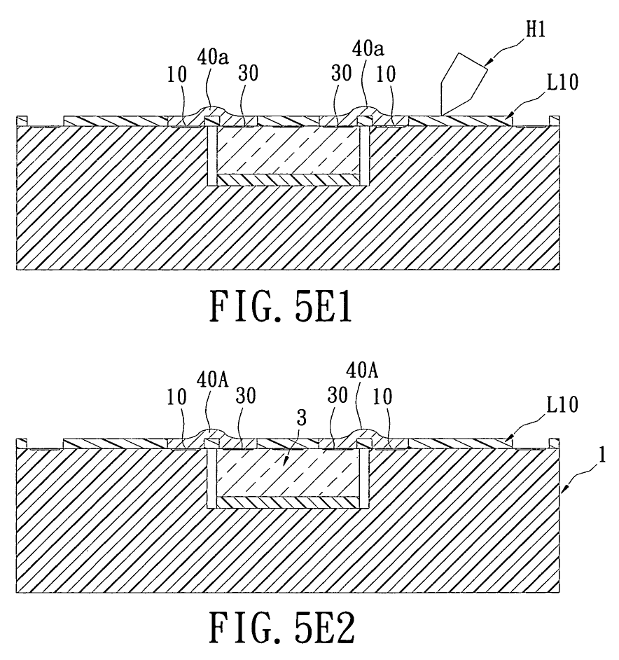

Referring to FIGS. 1 to 4 and 5A1 to 5G, the first embodiment of the present invention provides a method of packaging an LED array module. FIG. 1 shows a flow chart of a method of packaging an LED array module of the present invention. FIG. 2 shows a schematic view of a wafer that has been patterned. FIG. 3 shows an enlarged view of A part of FIG. 2. FIG. 4 shows a cross-sectional view along line 4-4 of FIG. 2. FIGS. 5A1 to 5G show cross-sectional, schematic views of a packaging process according to the present embodiment of the present invention, respectively.

Referring to FIGS. 1, and 2 to 4 again, The method of the first embodiment includes: providing a wafer W that has been patterned, and the wafer having a plurality of drive IC (Integrated Circuit) structures 1 and each drive IC structure 1 having a plurality of drive IC pads 10 (S100); and forming at least one concave groove 11 (that is a receiving space) on a top side of the drive IC structure 1 (S102). The drive IC pads 10 are straightly arranged on the drive IC structure 1. The at least one concave groove 11 is formed on the top side of the drive IC structure 1 via dry etching, wet etching, machining, or any forming method.

Referring to FIGS. 5A1 to 5G again, the step S1 discloses the manufacturing processes of each drive IC structure 1. The step S1 includes the step S104a to step S116.

Referring to FIG. 5A1, forming an adhesive element 2 on a lower surface 300 of the at least one LED array 3 (S104a). Alternatively, referring to FIG. 5A2, forming an adhesive element 2 on a base surface 110 of the at least one concave groove 11 (S104b). The adhesive element 2 can be a silver adhesive, a polymide, or any adhesive colloid.

Referring to FIGS. 5B1 and 5B2 (FIG. 5B1 is a cross-sectional view and FIG. 5B2 is a top view), the method of the first embodiment further includes: receiving at least one LED array 3 in the at least one concave groove 11, the at least one LED array 3 having a plurality of LED pads 30 corresponding to the drive IC pads 10 and a plurality of LED dies 31 corresponding to the LED pads 30 (S106). Moreover, the adhesive element 2 is arranged between the at least one LED array 3 and the drive IC structure 1.

Furthermore, the LED array module further includes two width gaps G formed between the at least one LED array 3 and the drive IC structure 1. Each width gap G has a width is between 5 and 10 μm. Each width gap G has a height is about 10 μm. In addition, the LED pads 30 are straightly arranged on the at least one LED array 3, that is same as the drive IC pads 10. Each LED die 31 has a positive electrode side 310 and a negative electrode side 311 respectively electrically connected with two corresponding LED pads 30.

Referring to FIG. 5C, the method of the first embodiment further includes: forming an insulative layer L1 on the drive IC structure 1 and the at least one LED array 3 (S108). The insulative layer L1 is a positive photo resist. In other words, the insulative layer L1 is formed on the drive IC structure 1 and the at least one LED array 3 via a coating process and a pre-cure process.

Referring to FIG. 5D, the method of the first embodiment further includes: patterning the insulative layer L1 to form a patterned insulative layer L10 for covering over the width gaps G formed between the at least one LED array 3 and the drive IC structure 1 and exposing the drive IC pads 10 and the LED pads 30 (S110). In other words, the patterned insulative layer L10 is formed via using UV light to illuminate the insulative layer L1 and using a mask M with a predetermined pattern to shade a part of the insulative layer L1 from the UV light.

Referring to FIGS. 5E1 and 5E2 (FIG. 5E1 is a cross-sectional view and FIG. 5E2 is a top view), the method of the first embodiment further includes: forming each liquid conductive material 40a between each corresponding drive IC pad 10 and each corresponding LED pad 30 via printing or coating (S112) such as using a printing head H1. Referring to FIG. 5E2, the method of the first embodiment further includes: curing the liquid conductive materials 40a to make the liquid conductive materials 40a become the conductive elements 40A (S114). In other words, the conductive elements 40A are formed between the drive IC structure 1 and the at least one LED array 3.

Referring to FIG. 5F, the method of the first embodiment further includes: removing a part of the patterned insulative layer L10 formed on the at least one LED array 3 (in order to expose the LED dies 31) to accomplish the LED array module P1 (S116).

Furthermore, after the step S116, each packaged LED array module P1 is cut from the wafer W (S118). It means that each drive IC structure 1 is cut from a wafer that has been patterned.

Referring to FIG. 5G, the method of the first embodiment further includes: arranging the drive IC structure 1 on a PCB 5 that has at least one input/output pad 50 (FIG. 5G shows two input/output pads 50) (S120); and forming a conductive structure 6 electrically connected between the drive IC structure 1 and the at least one input/output pad 50 (FIG. 5G shows two conductive structures 6) (S122). The conductive structure 6 is formed between one power pad 10a of the drive IC structure 1 and the at least one input/output pad 50 (FIG. 5G shows two pairs of power pad 10a and the at least one input/output pad 50) via a wire-bonding process.

Referring to FIG. 5G again, the packaged LED array module P1 includes a drive IC structure 1, an adhesive element 2, at least one LED array 3, and a plurality of conductive elements 40A. The drive IC structure 1 has at least one concave groove 11 and a plurality of drive IC pads 10 formed on a top side thereof. The adhesive element 2 is formed between the at least one LED array 3 and the drive IC structure 1. The at least one LED array 3 is received in the at least one concave groove 11. The at least one LED array 3 has a plurality of LED pads 30 and a plurality of LED dies 31 corresponding to the LED pads 30. The conductive elements 40A is electrically connected between the drive IC structure 1 and the at least one LED array 3 (Each conductive element 40A is electrically connected between each corresponding drive IC pad 10 and each corresponding LED pad 30).

Moreover, the packaged LED array module P1 can be arranged on a PCB 5 that has at least one input/output pad 50. A conductive structure 6 is electrically connected between the power pad 1a and the at least one input/output pad 50.

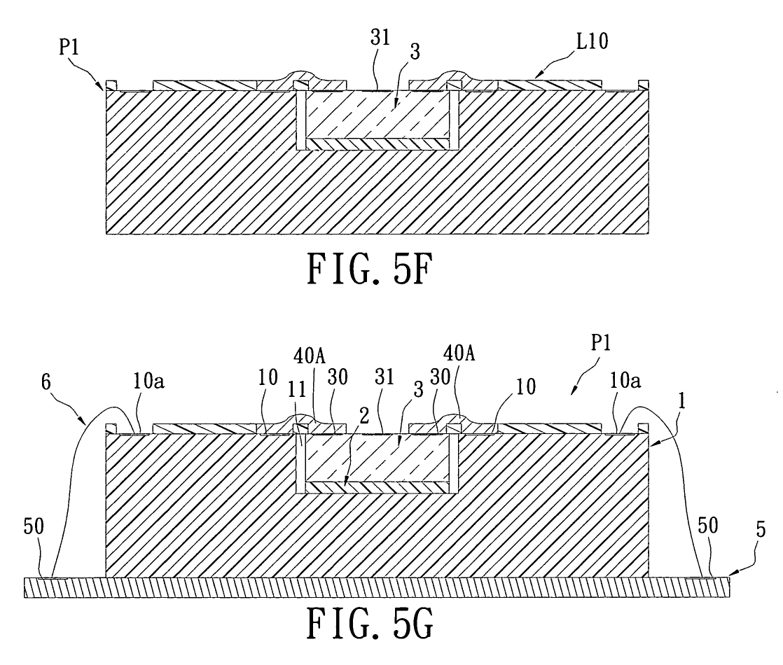

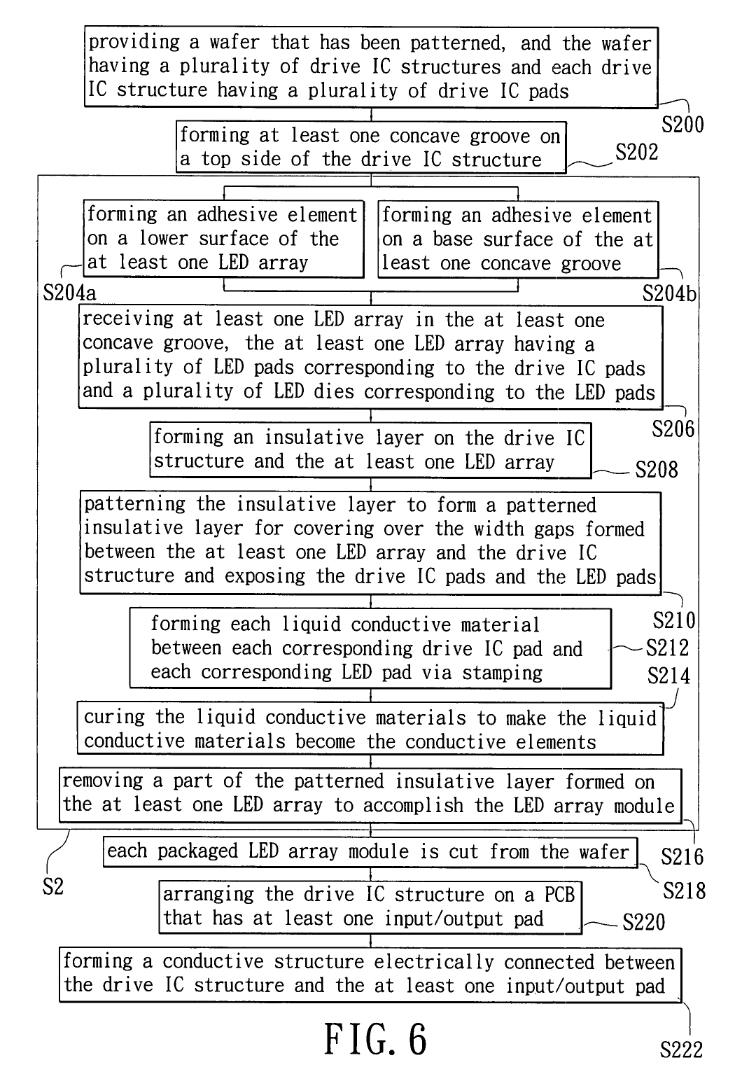

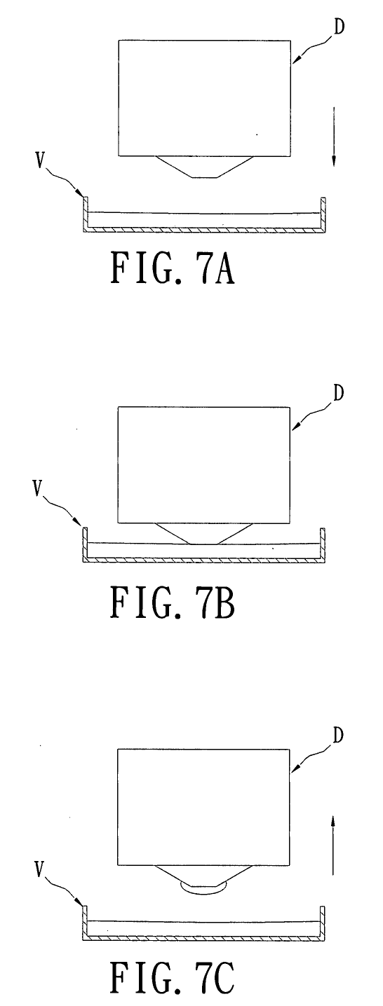

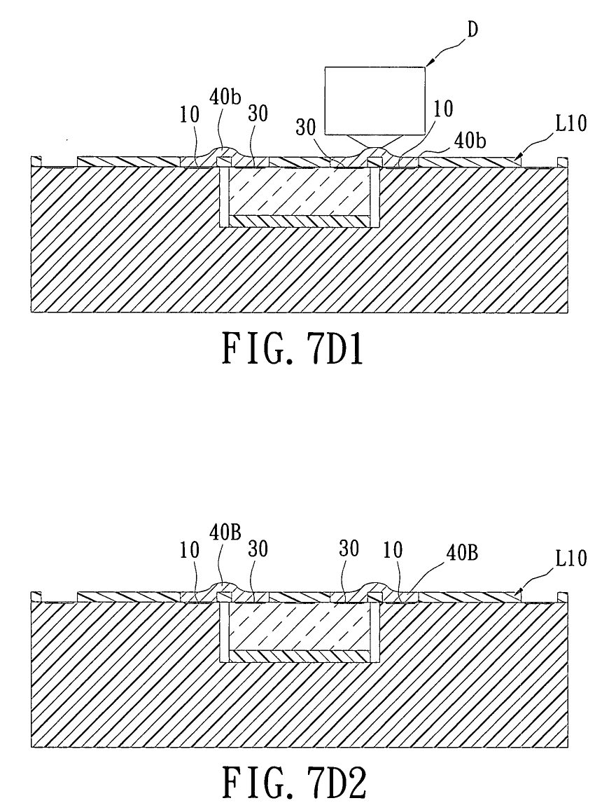

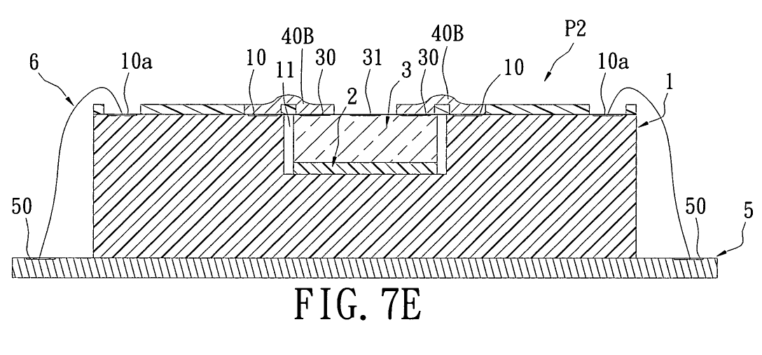

Referring to FIGS. 6 and 7A to 7E, the second embodiment of the present invention provides a method of packaging an LED array module. FIG. 6 shows a flow chart of a method of packaging an LED array module according to the second embodiment of the present invention. FIGS. 7A to 7E show cross-sectional, schematic views of a packaging process according to the second embodiment of the present invention, respectively. The step S2 discloses the manufacturing processes of each drive IC structure 1. The step S2 includes the step S204a to step S216.

Referring to FIGS. 1 and 6, the steps S200 to S210 and the steps S216 to S222 of the second embodiment are same as the steps S100 to S110 and the steps S116 to S122 of the first embodiment. The difference between the second embodiment and the first embodiment is that solidifying a plurality of liquid conductive materials 40b to form a plurality of conductive elements 40B electrically connected between the drive IC structure 1 and the at least one LED array 3 via stamping. In other words, each conductive element 40B is electrically connected between each corresponding drive IC pad 10 and each corresponding LED pad 30.

Referring to FIGS. 7A to 7D1, after the step S210, the method of the second embodiment further includes: forming each liquid conductive material 40b between each corresponding drive IC pad 10 and each corresponding LED pad 30 via stamping (S212). In other words, the method of the second embodiment further includes repeatedly stamping the liquid conductive materials 40b from a vessel V to a place between each corresponding drive IC pad 10 and each corresponding LED pad 30 via a stamping device D (the steps of FIGS. 7A to 7D1 are repeated). Therefore, each liquid conductive material 40b is electrically connected between each corresponding drive IC pad 10 and each corresponding LED pad 30.

Referring to FIG. 7D2, the method of the second embodiment further includes: curing the liquid conductive materials 40b to make the liquid conductive materials 40b become the conductive elements 40B (S214). In other words, the conductive elements 40B are formed between the drive IC structure 1 and the at least one LED array 3.

Referring to FIG. 7E, the method of the second embodiment further includes: removing a part of the patterned insulative layer L10 formed on the at least one LED array 3 (in order to expose the LED dies 31) to accomplish the LED array module P2. Hence, the packaged LED array module P2 includes a drive IC structure 1, an adhesive element 2, at least one LED array 3, and a plurality of conductive elements 40B. The drive IC structure 1 has, at least one concave groove 11 and a plurality of drive IC pads 10 formed on a top side thereof. The adhesive element 2 is formed between the at least one LED array 3 and the drive IC structure 1. The at least one LED array 3 is received in the at least one concave groove 11. The at least one LED array 3 has a plurality of LED pads 30 and a plurality of LED dies 31 corresponding to the LED pads 30. The conductive elements 40B is electrically connected between the drive IC structure 1 and the at least one LED array 3 (Each conductive element 40B is electrically connected between each corresponding drive IC pad 10 and each corresponding LED pad 30).

Moreover, the packaged LED array module P2 can be arranged on a PCB 5 that has at least one input/output pad 50. A conductive structure 6 is electrically connected between the power pad 1a and the at least one input/output pad 50.

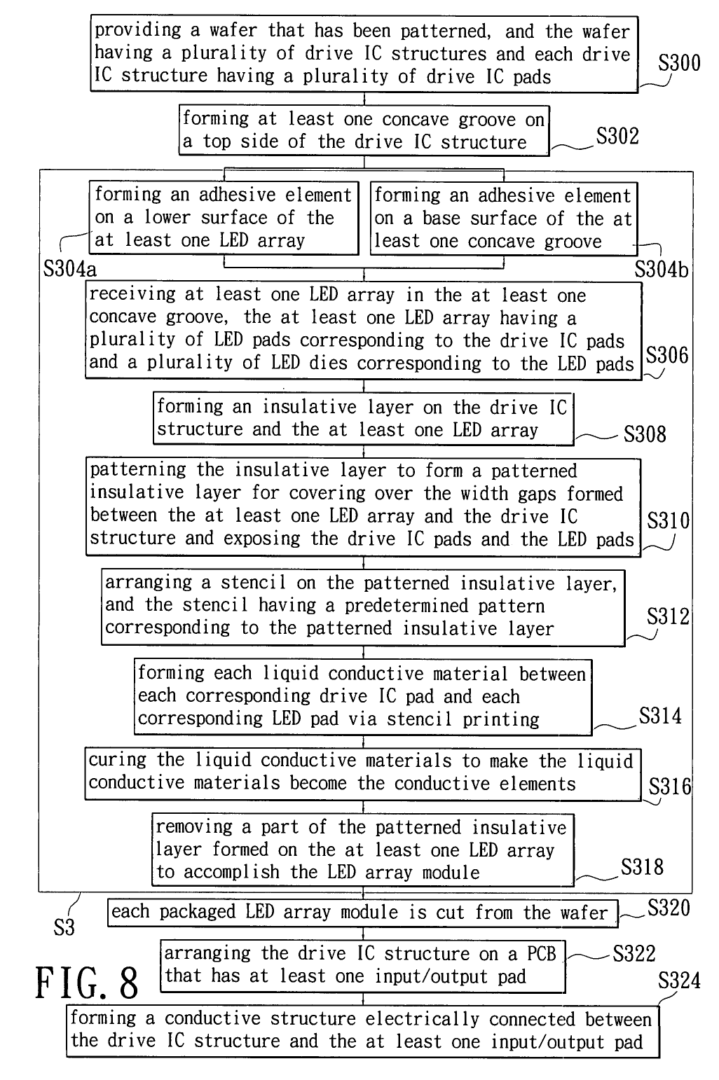

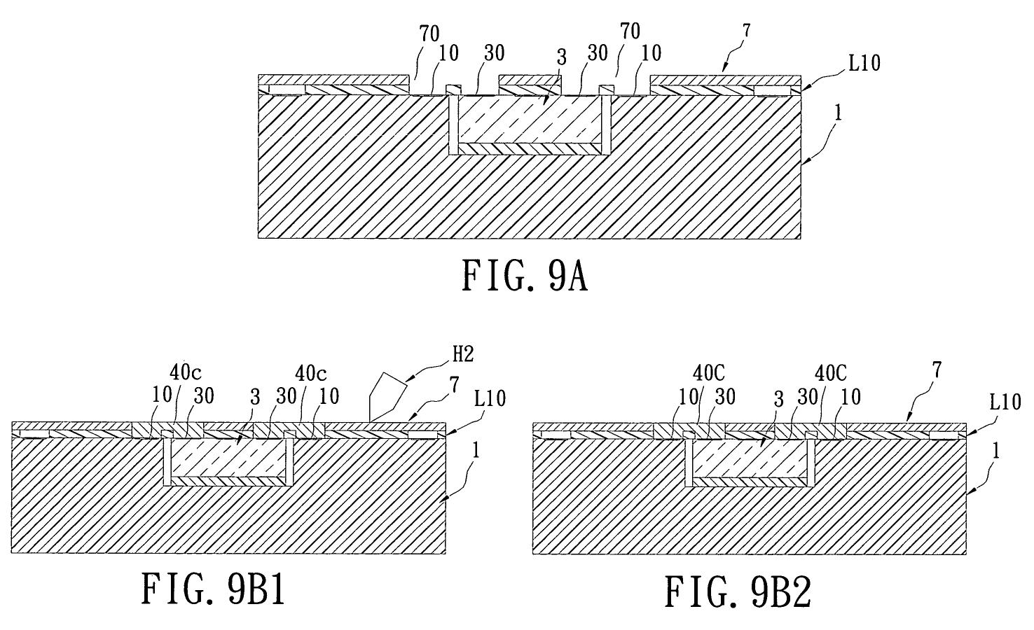

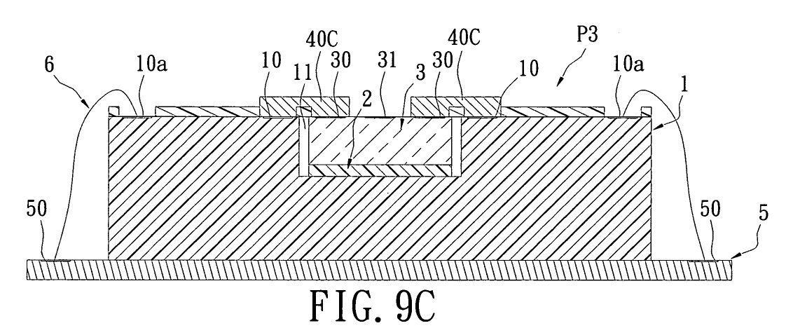

Referring to FIGS. 8 and 9A to 9C, the third embodiment of the present invention provides a method of packaging an LED array module. FIG. 8 shows a flow chart of a method of packaging an LED array module according to the third embodiment of the present invention. FIGS. 9A to 9C show cross-sectional, schematic views of a packaging process according to the third embodiment of the present invention, respectively. The step S3 discloses the manufacturing processes of each drive IC structure 1. The step S3 includes the step S304a to step S318.

Referring to FIGS. 1 and 8, the steps S300 to S310 and the steps S318 to S324 of the third embodiment are same as the steps S100 to S110 and the steps S116 to S122 of the first embodiment. The difference between the third embodiment and the first embodiment (or the second embodiment) is that solidifying a plurality of liquid conductive materials 40c to form a plurality of conductive elements 40C electrically connected between the drive IC structure 1 and the at least one LED array 3 via stencil printing. In other words, each conductive element 40C is electrically connected between each corresponding drive IC pad 10 and each corresponding LED pad 30.

Referring to FIG. 9A, after the step S310, the method of the third embodiment further includes: arranging a stencil 7 on the patterned insulative layer L10, and the stencil 7 having a predetermined pattern 70 corresponding to the patterned insulative layer L10 (S312). Hence, an inverse U-shaped concave groove is formed between each drive IC pad 10 and each LED pad 30 via matching the patterned insulative layer L10 and the predetermined pattern 70 of the stencil 7.

Referring to FIG. 9B1, the method of the third embodiment further includes: forming each liquid conductive material 40c between each corresponding drive IC pad 10 and each corresponding LED pad 30 via stencil printing (S314). In other words, each liquid conductive material 40c is formed between each corresponding drive IC pad 10 and each corresponding LED pad 30 via matching the patterned insulative layer L10 and the predetermined pattern 70 of the stencil 7 and using a printing head H2.

Referring to FIG. 9B2, the method of the third embodiment further includes: curing the liquid conductive materials 40c to make the liquid conductive materials 40c become the conductive elements 40C (S316).

Referring to FIG. 9C, the method of the third embodiment further includes: removing a part of the patterned insulative layer L10 formed on the at least one LED array 3 (in order to expose the LED dies 31) to accomplish the LED array module P3. Hence, the packaged LED array module P3 includes a drive IC structure 1, an adhesive element 2, at least one LED array 3, and a plurality of conductive elements 40C. The drive IC structure 1 has at least one concave groove 11 and a plurality of drive IC pads 10 formed on a top side thereof. The adhesive element 2 is formed between the at least one LED array 3 and the drive IC structure 1. The at least one LED array 3 is received in the at least one concave groove 11. The at least one LED array 3 has a plurality of LED pads 30 and a plurality of LED dies 31 corresponding to the LED pads 30. The conductive elements 40C is electrically connected between the drive IC structure 1 and the at least one LED array 3 (Each conductive element 40C is electrically connected between each corresponding drive IC pad 10 and each corresponding LED pad 30).

Moreover, the packaged LED array module P3 can be arranged on a PCB 5 that has at least one input/output pad 50. A conductive structure 6 is electrically connected between the power pad 1 a and the at least one input/output pad 50.

Furthermore, the drive IC pads 10 can be interlacedly arranged on the drive IC structure 1 and the LED pads 30 can be interlacedly arranged on the at least one LED array 3. Therefore, the LED dies 31 of the at least one LED array 3 can be arranged compactly together.

In conclusion, the LED array module (P1, P2, P3) is a light exposure module that can be applied to EPG (Electrophotography) printer.

Moreover, the feature of the present invention includes: etching at least one concave groove 11 on the drive IC structure 1; arranging a light-emitting element array such as an LED array in the at least one concave groove 11; and then achieving high density electrical connection with 600-1200 dpi via printing, coating, stamping or stencil printing. Hence, the present invention can reduce product size, material cost, and manufacturing cost due to high density electrical connection.

Hence, the present invention utilize printing, coating, stamping or stencil printing to manufacture a conductive structure for electrically connecting between the at least one LED array 3 and the drive IC structure 1 without using wire-bonding process such as prior art that needs to take a long time. Hence, the present invention not only can reduce product size, material cost, and manufacturing cost, but also increases production speed.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method of packaging an LED array module, comprising:
forming at least one concave groove on a top side of a drive IC structure;
receiving at least one LED array in the at least one concave groove; and
solidifying a plurality of liquid conductive materials to form a plurality of conductive elements electrically connected between the drive IC structure and the at least one LED array.

2. The method as claimed in claim 1, wherein the drive IC structure is cut from a wafer that has been patterned.

3. The method as claimed in claim 1, wherein the at least one concave groove is formed via etching or machining.

4. The method as claimed in claim 1, further comprising an adhesive element disposed between the at least one LED array and the drive IC structure.

5. The method as claimed in claim 4, wherein the adhesive element is a silver adhesive or a polymide.

6. The method as claimed in claim 1, further comprising forming an adhesive element on a lower surface of the at least one LED array for making the adhesive element formed between the at least one LED array and the drive IC structure, before receiving the at least one LED array in the at least one concave groove.

7. The method as claimed in claim 1, further comprising forming an adhesive element on a base surface of the at least one concave groove for making the adhesive element formed between the at least one LED array and the drive IC structure, before receiving the at least one LED array in the at least one concave groove.

8. The method as claimed in claim 1, wherein the drive IC structure has a plurality of drive IC pads, the at least one LED array has a plurality of LED pads corresponding to the drive IC pads, and each conductive element is electrically connected between each corresponding drive IC pad and each corresponding LED pad.

9. The method as claimed in claim 8, wherein the drive IC pads are straightly arranged on the drive IC structure and the LED pads are straightly arranged on the at least one LED array.

10. The method as claimed in claim 8, wherein the drive IC pads are interlacedly arranged on the drive IC structure and the LED pads are interlacedly arranged on the at least one LED array.

11. The method as claimed in claim 8, wherein the at least one LED array has a plurality of LED dies corresponding to the LED pads, and each LED die has a positive electrode side and a negative electrode side respectively electrically connected with two corresponding LED pads.

12. The method as claimed in claim 8, wherein before the step of solidifying the liquid conductive material, the method further comprises:
forming an insulative layer on the drive IC structure and the at least one LED array; and
patterning the insulative layer to form a patterned insulative layer for covering over two width gaps formed between the at least one LED array and the drive IC structure and exposing the drive IC pads and the LED pads.

13. The method as claimed in claim 12, wherein the step of solidifying the liquid conductive material further comprises:
forming each liquid conductive material between each corresponding drive IC pad and each corresponding LED pad via printing or coating;
curing the liquid conductive materials to make the liquid conductive materials become the conductive elements; and
removing a part of the patterned insulative layer formed on the at least one LED array to accomplish the LED array module.

14. The method as claimed in claim 12, wherein the step of solidifying the liquid conductive material further comprises:
forming each liquid conductive material between each corresponding drive IC pad and each corresponding LED pad via stamping;
curing the liquid conductive materials to make the liquid conductive materials become the conductive elements; and
removing a part of the patterned insulative layer formed on the at least one LED array to accomplish the LED array module.

15. The method as claimed in claim 12, wherein the step of solidifying the liquid conductive material further comprises:
arranging a stencil on the patterned insulative layer, wherein the stencil has a predetermined pattern corresponding to the patterned insulative layer;
forming each liquid conductive material between each corresponding drive IC pad and each corresponding LED pad via stencil printing;
curing the liquid conductive materials to make the liquid conductive materials become the conductive elements; and
removing a part of the patterned insulative layer formed on the at least one LED array to accomplish the LED array module.

16. The method as claimed in claim 1, further comprising two width gaps formed between the at least one LED array and the drive IC structure, wherein each width gap has a width is between 5 and 10 μm.

17. The method as claimed in claim 1, wherein after the step of solidifying the liquid conductive material, the method further comprising:
arranging the drive IC structure on a PCB that has at least one input/output pad; and
forming a conductive structure electrically connected between the drive IC structure and the at least one input/output pad.

18. The method as claimed in claim 17, wherein the conductive structure is formed via a wire-bonding process.
